(19) United States
(12) Patent Application Publication
(10) Pub. No.: US 2016/0355393 A1
(43) Pub. Date: Dec. 8, 2016

(54) CHIP PACKAGE AND MANUFACTURING METHOD THEREOF

(71) Applicant: XINTEC INC., Taoyuan City (TW)

(72) Inventors: Tsang-Yu LIU, Zhubei City (TW); Wei-Luen SUEN, New Taipei City (TW); Po-Han LEE, Taipei City (TW)

(21) Appl. No.: 15/171,971

(22) Filed: Jun. 2, 2016

Related U.S. Application Data
(60) Provisional application No. 62/172,607, filed on Jun. 8, 2015.

(51) Int. Cl. B81B 3/00; B81C 1/00

(52) U.S. Cl. CPC B81B 3/0081; B81C 1/0069

(57) ABSTRACT

A chip package includes a chip having an upper surface and a lower surface. A sensing element is disposed on the upper surface of the chip, and a thermal dissipation layer is disposed below the lower surface of the chip. A plurality of thermal dissipation external connections are disposed below the thermal dissipation layer and in contact with the thermal dissipation layer.

### RELATED APPLICATIONS

This application claims priority to U.S. Provisional Application Ser. No. 62/172,607, filed Jun. 8, 2015, which is herein incorporated by reference.

### BACKGROUND

Field of the Invention

The present invention relates to a chip package and a manufacturing method thereof.

Description of Related Art

With the needs of electronic devices in multifunction and compact appearance, semiconductor chips adapted to the electronic devices is not only getting miniaturized, but also face higher and higher challenges, due to the increase in wiring density, of fabricating a semiconductor chip package in subsequent processes. Wafer-level chip package (WLCP) is one of the methods of packaging the semiconductor chip, which refers to that all the manufactured chips are packaged and tested, and then the wafer is cut into a single chip package.

However, under the miniaturization and the increased wiring density of the semiconductor chip, enormous heat generated during chip operation cause negative effect on the efficacy. Moreover, it also degrades the characteristic and lifetime of the chip, which dramatically increase cost. Accordingly, a chip having thermal dissipation function and a method of manufacturing the same is one of important development ways in chip package industry.

### SUMMARY

Therefore, the present invention provides a chip package and a method of manufacturing the same which can transmit heat during chip operation effectively so that the chip package has higher reliability.

One aspect of the present invention provides a chip package. The chip package includes a chip having an upper surface and a lower surface, a sensing element disposed at the upper surface, a thermal dissipation layer disposed at the lower surface, and a plurality of thermal dissipation external connections disposed underneath and in contact with the thermal dissipation layer.

According to some embodiments of the present invention, the thermal dissipation layer is disposed at the lower surface corresponding to the sensing element.

According to some embodiments of the present invention, the chip package further includes an insulating layer disposed on the lower surface and covering the thermal dissipation layer, and a protective layer disposed at the lower surface and covering the insulating layer. A lower surface of the protective layer has a plurality of openings penetrating the protective layer and the insulating layer and exposing the thermal dissipation layer, wherein the thermal dissipation external connections are disposed within the openings and in contact with the thermal dissipation layer.

According to some embodiments of the present invention, the material of the thermal dissipation layer is a metal material.

According to some embodiments of the present invention, the metal material used in the thermal dissipation layer is aluminum.

According to some embodiments of the present invention, the thickness of the thermal dissipation layer is between 1 μm to 1.5 μm.

According to some embodiments of the present invention, the thermal dissipation external connections are solder balls.

One aspect of the present invention provides a method of manufacturing a chip package. The method starts with providing a wafer having an upper surface and a lower surface. The wafer further has a plurality of chips, and each of the chips includes a sensing element disposed at the upper surface. Then, a thermal dissipation layer is formed at the lower surface, and an insulating layer is formed covering the thermal dissipation layer. A protective layer is formed covering the insulating layer and the thermal dissipation layer after a portion of the insulating layer is removed to expose the thermal dissipation layer. Then, a portion of the protective layer is removed to expose the thermal dissipation layer, and a plurality of thermal dissipation connections are formed underneath and in contact with the thermal dissipation layer.

According to some embodiments of the present invention, the chip further includes a conductive pad disposed underneath the upper surface and electrically connected to the sensing element.

According to some embodiments of the present invention, the method further includes forming a plurality of vias in the wafer, wherein the vias extends from the lower surface of the wafer toward the upper surface and exposes the conductive pad.

According to some embodiments of the present invention, the insulating layer covers sidewalls of the vias and the conductive pad.

According to some embodiments of the present invention, a portion of the protective layer is removed to expose the thermal dissipation layer, and a portion of the insulating layer is removed to expose the conductive pad meanwhile.

According to some embodiments of the present invention, the method further includes forming a conductive layer underneath the insulating layer, wherein the protective layer covers the conductive layer.

According to some embodiments of the present invention, a portion of the protective layer is removed to expose the thermal dissipation layer, and a portion of the protective layer is removed to expose the conductive layer meanwhile.

According to some embodiments of the present invention, the method further includes forming a plurality of conductive connections underneath and in contact with the conductive layer, and the thermal dissipation connections and the conductive connections are solder balls and formed meanwhile in the same process step.

According to some embodiments of the present invention, the method further includes separating two adjacent chips along a scribe line to form a chip package.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a chip package, in accordance with some embodiments of the present invention;

FIG. 2 is a cross-sectional view of a chip package, in accordance with some other embodiments of the present invention;

FIGS. 3A to 3H are cross-sectional views of the chip package in FIG. 1 at various stages of fabrication; and

FIGS. 4A to 4H are cross-sectional views of the chip package in FIG. 2 at various stages of fabrication.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

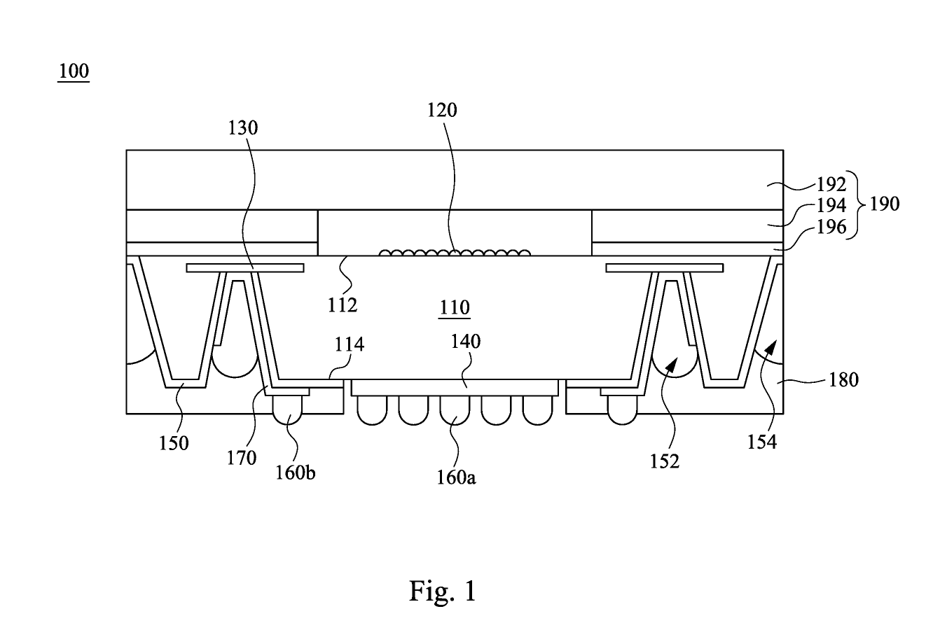

Please refer to FIG. 1 first; FIG. 1 illustrates a cross-sectional view of a chip package in accordance with some embodiments of the present invention. As shown in FIG. 1, a chip package 100 includes a chip 110 which has an upper surface 112 and a lower surface 114 opposite to each other. A sensing element 120 is disposed on the upper surface 112 of the chip 110, and a conductive pad 130 is disposed underneath the upper surface 112 of the chip 110 and electrically connected to the sensing element 120. In some embodiments of the present invention, the chip 110 includes a semiconductor element, an inter-layer dielectric (ILD), an inter-metal dielectric (IMD), a passivation layer, and an interconnect metal structure, wherein the conductive pad 130 is one of the metal layers of the interconnect metal structure. In some embodiments, the conductive pad 130 can be used as a place where each sensing element 120 forms a solder ball or a wire-bonding respectively after packaging. The material of the conductive pad 130 may be, for example, aluminum, copper, nickel, or other suitable metal materials.

In some embodiments of the present invention, the sensing element 120 may be, but not limited to, active or passive elements, electronic components of digital or analog integrated circuits, opto electronic devices, micro electro mechanical systems (MEMS), micro fluidic systems, physical sensors for detecting physical characteristics such as detecting heat, light, or pressure, RF circuits, accelerators, gyroscopes, micro actuators, surface acoustic wave devices, and pressure sensors.

Please continue referring to FIG. 1, a thermal dissipation layer 140 is disposed at the lower surface 114 of the chip 110, and the thermal dissipation layer 140 is further in contact with the lower surface 114 of the chip 110 to provide thermal dissipation routes for transmitting heat generated by sensing element 120 operation and preventing efficiency decrease or breakdown of the sensing element 120 when overheating. In some embodiments of the present invention, the thermal dissipation layer 140 is disposed at the place corresponding to the lower surface 114 of the sensing element 120 to provide better thermal dissipation efficiency. In some other embodiments of the present invention, the material of the thermal dissipation layer 140 is, but not limited to, aluminum, and other suitable metal materials can be used to manufacture the thermal dissipation layer 140. In some other embodiments of the present invention, the thickness of the thermal dissipation layer 140 ranges from 1 μm to 1.5 μm, and the best thickness is 1.2 μm.

Please continue referring to FIG. 1, the chip package 100 further includes a first via 152 extending from the lower surface 114 toward the upper surface 112 and exposing the conductive pad 130. An insulating layer 150 is disposed at the lower surface 114 of the chip 110 and covers sidewalls of the first via 152 rather than the thermal dissipation layer 140 and the conductive pad 130 in the first via 152. The lower surface 114 of the chip 110 further has a plurality of thermal dissipation external connections 160a in direct contact with the thermal dissipation layer 140. The thermal dissipation external connections 160a can further transmit the heat of the thermal dissipation layer 140 to the external. For example, in the following processes that the chip package 100 will be packaged into a printing circuit board, the thermal dissipation external connections 160a can transmit the heat generated by the sensing element 120 operation to the printing circuit board so as to not only decrease the temperature of the chip package 100 effectively but also increase the efficiency of the sensing element 120. In some embodiments of the present invention, the material of the insulating layer insulating layer 150 is silicon oxide, silicon nitride, silicon oxynitride, or other suitable insulating materials. In some other embodiments of the present invention, the thermal dissipation external connections 160a are solder balls, bumps which are industrially well-known structures, and the shape thereof can be, but not limited to, circular, ellipse, square, and rectangular, which are not used to limited the present invention.

Please continue referring to FIG. 1, the chip package 100 further includes a conductive layer 170 disposed underneath the insulating layer 150, and a portion of the conductive layer 170 is disposed in the first via 152 and in contact with the conductive pad 130 to be electrically connected to the conductive pad 130. In some embodiments of the present invention, the material of the conductive layer 170 may be, for example, aluminum, copper, or nickel, or other suitable metal materials. Furthermore, a plurality of conduction external connections 160b are disposed underneath the conductive layer 170 so that the conduction external connections 160b are electrically connected to the conductive pad 130 through the conductive layer 170. In other embodiments of the present invention, the conduction external connections 160b can be solder balls or bumps, which are industrially well-known structures, and the shape thereof can be circular, ellipse, square, rectangular, which are not be used to limit the present invention. In some other embodiments of the present invention, the thermal dissipation external connections 160a and the conduction external connections 160b are both solder balls.

In some embodiments of the present invention, a protective layer 180 is disposed at the lower surface 114 of the chip 110 and covers the insulating layer 150, the conductive layer 170, and a portion of the conduction external connections 160b. It should be noticed that the protective layer 180 does not cover the thermal dissipation layer 140 and the thermal dissipation external connections 160a. In some embodiments of the present invention, the material of the protective layer 180 is epoxy resin, such as solder mask.

In some other embodiments of the present invention, the chip package 100 further includes an optical cap 190 disposed at the upper surface 112 of the chip 110. The optical cap 190 includes a transparent substrate 192 and a dam structure 194, wherein the transparent substrate 192 is light-transmitting, and the dam structure 194 keeps a space between the transparent substrate 192 and the sensing element 120 and forms a space with the transparent substrate 192 to protective the sensing element 120. Furthermore, the optical cap 190 further includes an adhesive layer 196 making the dam structure 194 and the upper surface 112 of the chip 110 steadily combined with each other. In some embodiments of the present invention, the transparent substrate 192 can be glass or quartz, and the circular dam structure 194 includes epoxy resin, polyimide, photo resist, or silicon-based materials.

In some other embodiments of the present invention, the chip 110 further includes a second via 154 extending from the 114 of the chip 110 toward the upper surface 112 and exposing the adhesive layer 196. And the insulating layer 150 entirely covers sidewalls and the bottom of the second via 154. The second via 154 is used as a scribe line to cut the whole wafer into individual chip packages 110, which will be discussed later.

It should be known that the aforementioned elements and materials will not be mentioned repeatedly again. In the following description, chip packages in other embodiments will be discussed.

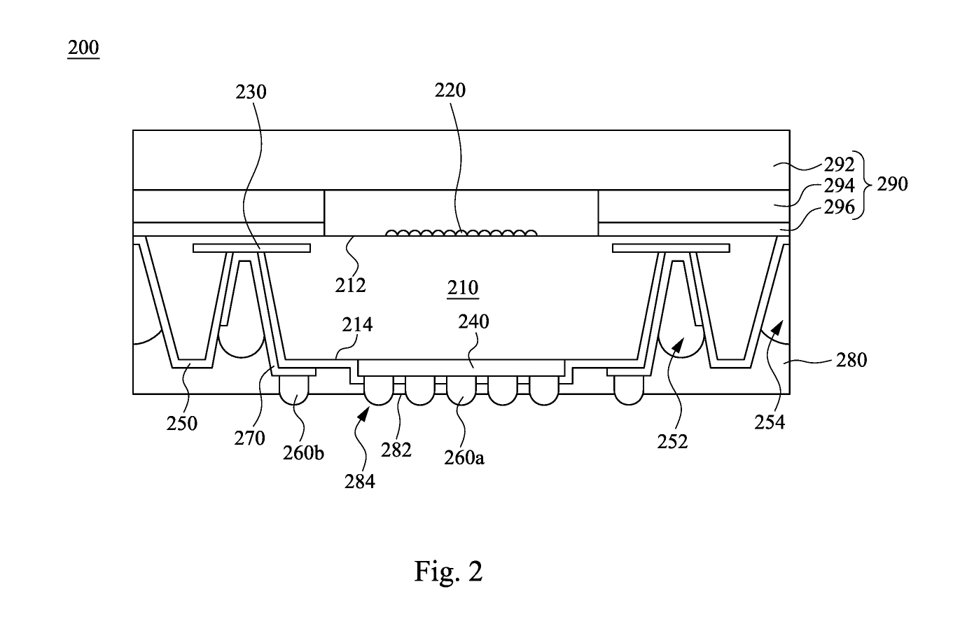

Please refer to FIG. 2. FIG. 2 illustrates a cross-sectional view of a chip package in some other embodiments of the present invention. As shown in FIG. 2, a chip package 200 includes a chip 210, and the chip 210 has an upper surface 212 and a lower surface 214 opposite to each other. A sensing element 220 is disposed on the upper surface 212 of the chip 210, and a conductive pad 230 is disposed underneath the upper surface 212 of the chip 210 and electrically connected to the sensing element 220. A thermal dissipation layer 240 is disposed at the lower surface 214 of the chip 210. Since the thermal dissipation layer 240 is in direct contact with the lower surface 214 of the chip 210, the thermal dissipation layer 240 can provide thermal dissipation routes for transmitting the heat generated from the sensing element 220 operation and preventing the efficiency decrease or breakdown of the sensing element 220 when overheating. In some embodiments of the present invention, the thermal dissipation layer 240 is disposed at the place corresponding to the lower surface 214 of the sensing element 220 to provide better thermal dissipation.

Please continue referring to FIG. 2, the chip package 200 further includes a first via 252 extending from the lower surface 214 of the chip 210 toward the upper surface 212 and exposing the conductive pad 230. An insulating layer 250 is disposed at the lower surface 214 of the chip 210, covering the thermal dissipation layer 240 and sidewalls of the first via 252. The chip package 200 further includes a conductive layer 270 disposed underneath the insulating layer 250, and a portion of the conductive layer 270 is disposed in the first via 252 and in contact with the conductive pad 230 to be electrically connected to the conductive pad 230. Furthermore, a plurality of conduction external connections 260b are disposed underneath the conductive layer 270 so that the conduction external connections 260b can be electrically connected to the conductive pad 230 through the conductive layer 270. In some other embodiments of the present invention, the conduction external connections 260b are solder balls or bumps which are industrially well-known structures, and the shape thereof can be circular, ellipse, square, rectangular, which are not used to limit the present invention.

Please continue referring to FIG. 2, a protective layer 280 disposed at the lower surface 214 of the chip 210 covers the insulating layer 250 and the conductive layer 270. In some embodiments of the present invention, the material of the protective layer 280 includes epoxy resin, such as solder mask. The difference between the chip package chip package 200 in FIG. 2 and the chip package 100 in FIG. 1 is that the protective layer 280 and the insulating layer 250 evenly cover the thermal dissipation layer 240, and a lower surface 282 of the protective layer 280 has a plurality of openings 284 exposing the thermal dissipation layer 240. To be more precise, the opening 284 extends through the protective layer 280 and insulating layer 250 from the lower surface 282 of the protective layer 280 and exposes the thermal dissipation layer 240. A plurality of thermal dissipation external connections 260a are disposed in the opening 284 and in direct contact with the thermal dissipation layer 240. The thermal dissipation external connections 260a can further transmit the heat of the thermal dissipation layer 240 to the external. For example, in the following processes that the chip package chip package 200 will be packaged into a printing circuit board, the thermal dissipation external connections 260a can transmit the heat of the sensing element 220 operation to the printing circuit board, which not only decrease the temperature of the chip package chip package 200, but also increase the efficiency of the sensing element 220. In other embodiments of the present invention, the thermal dissipation external connections 260a are solder balls or bumps which are industrially well-known structures, and the shape thereof can be circular, ellipse, square, rectangular, which are not used to limit the present invention. In some other embodiments of the present invention, the thermal dissipation external connections 260a and the conduction external connections 260b are solder balls.

In some other embodiments of the present invention, the chip package chip package 200 further includes an optical cap 290 disposed at the upper surface 212 of the chip 210. The optical cap 290 includes a transparent substrate 292 and a dam structure 294, wherein the transparent substrate 292 is light-transmitting and the dam structure 294 keeps a space between the transparent substrate 292 and the sensing element 220 and forms a space with the transparent substrate 292 to protect the sensing element 220. Furthermore, the optical cap 290 further includes an adhesive layer 296 so that the dam structure 294 and the upper surface 212 of the chip 210 can be steadily combined.

In some other embodiments of the present invention, the chip package chip package 200 further includes a second via 254 extending from the lower surface 214 of the chip 210 toward the upper surface 212 to expose the adhesive layer 296, and the insulating layer 250 entirely covers sidewalls and the bottom of the second via 254. The second via 254 is used as a scribed line to cut the entire wafer into individual chip package chip packages 200, which will be discussed later.

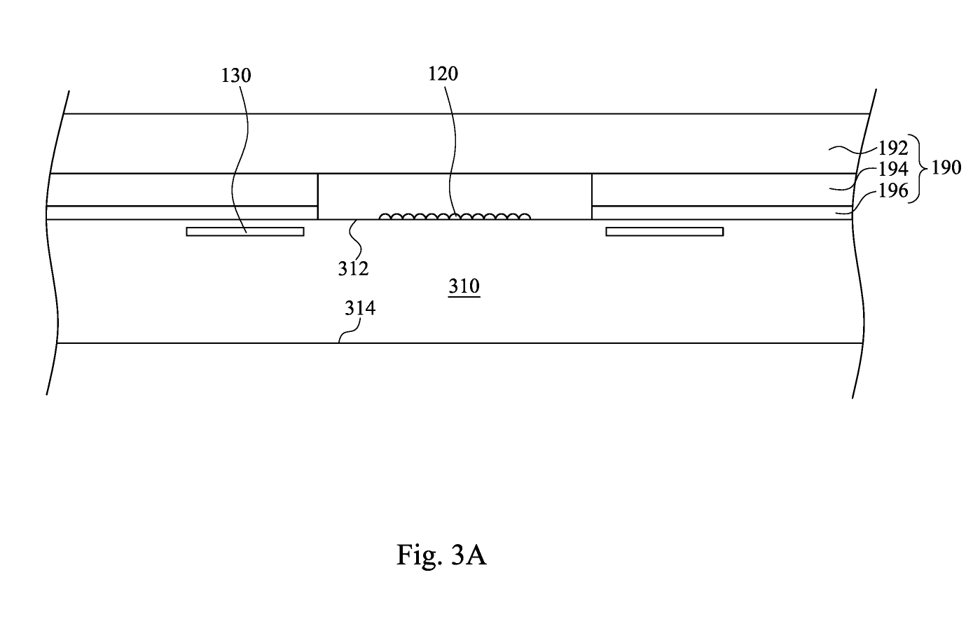

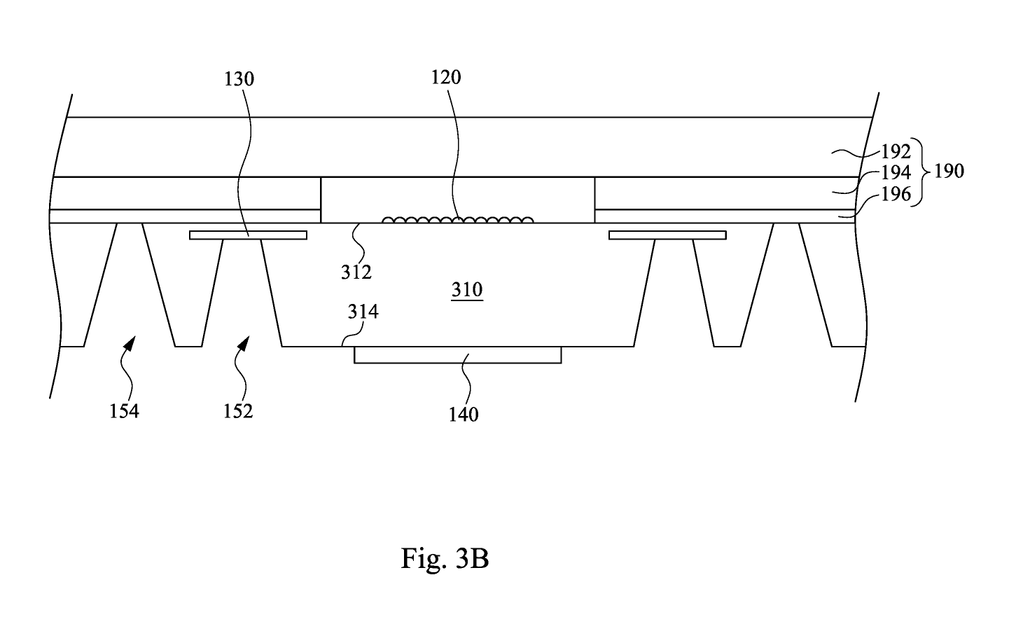

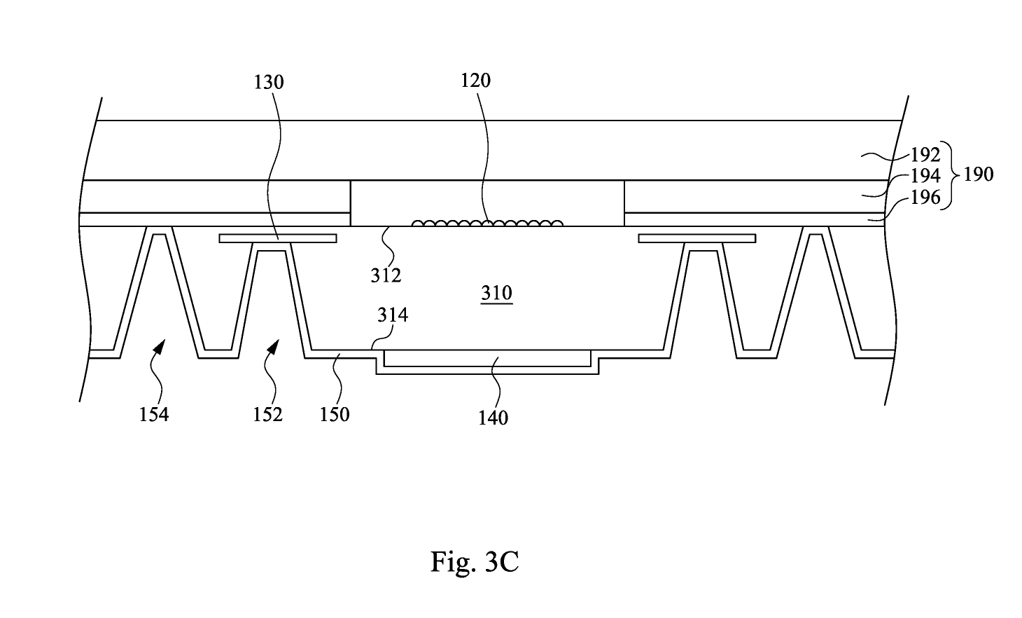

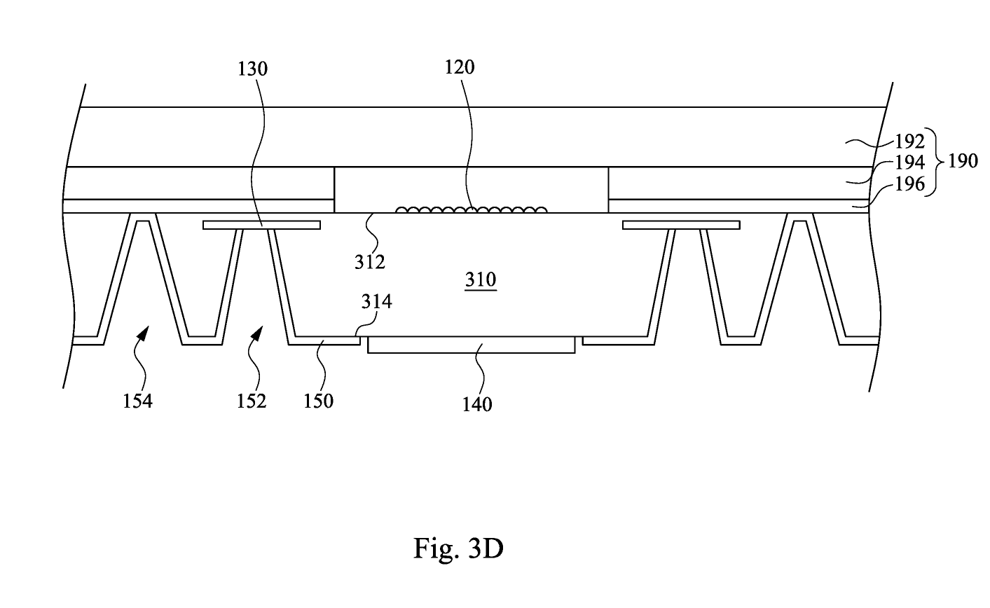

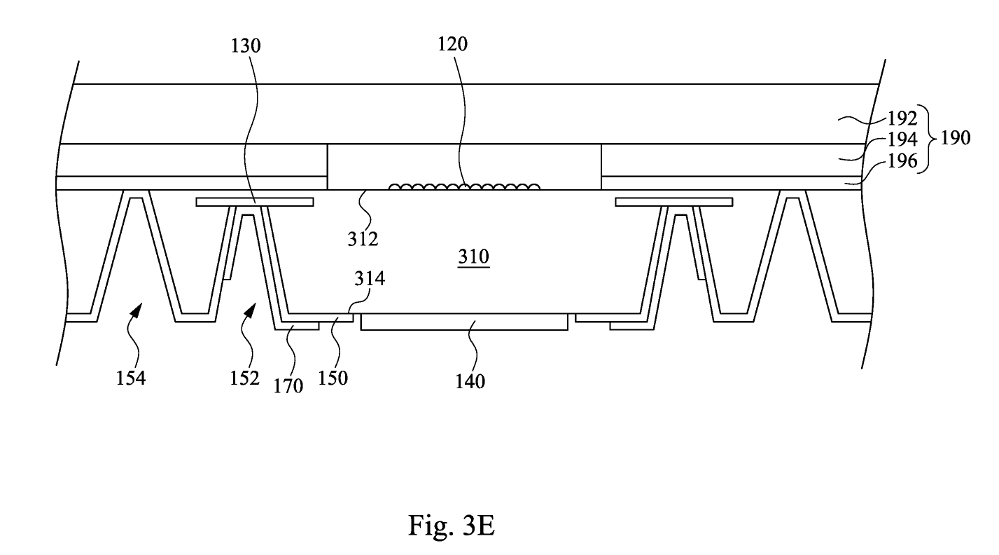

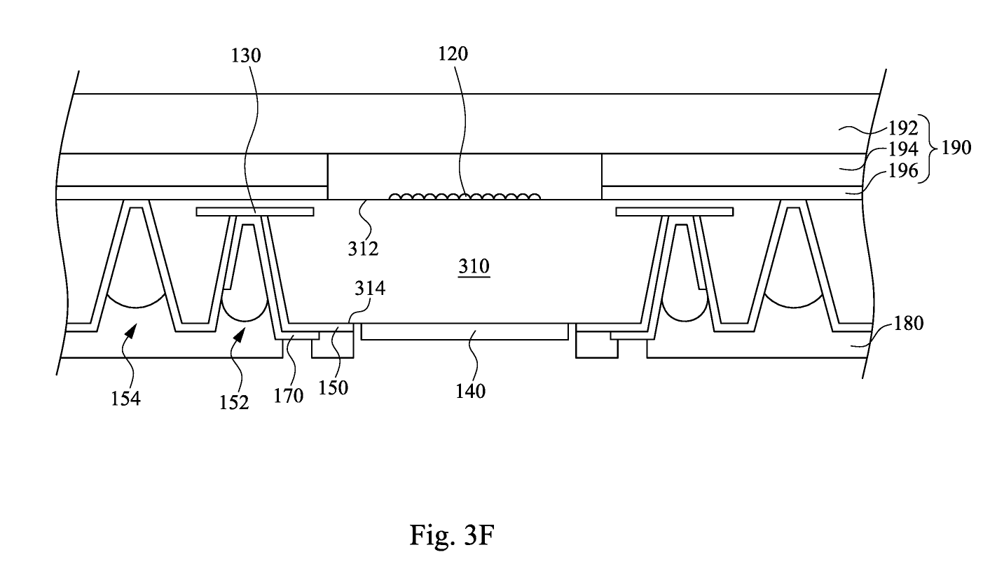

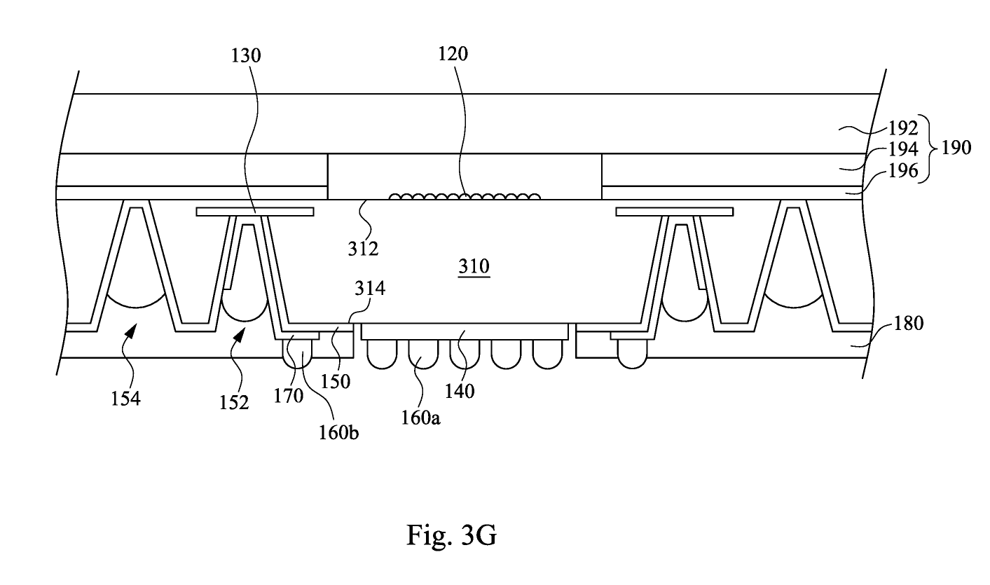

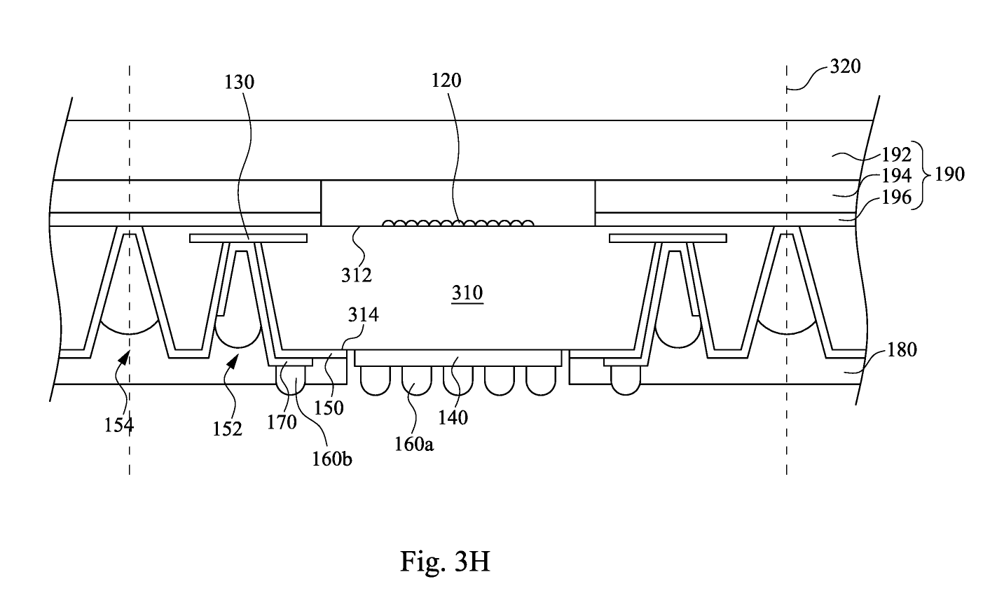

Please refer to FIG. 3A-3H for further understanding of the spirit of the present invention. FIGS. 3A-3H illustrate cross-sectional views of the chip package in FIG. 1 at various stages of fabrication. Please refer to FIG. 3A first, a wafer 310 having a plurality of chips is provided and an upper surface 312 and a lower surface 314 opposite to each other. The wafer 310 includes a semiconductor element, an inter-layer dielectric (ILD), an inter-metal dielectric (IMD), a passivation layer, and an interconnect metal structure, wherein the conductive pad 130 is one of the metal layers of the interconnect metal structure. For simplicity, FIG. 3A only illustrates a portion of the chips of the wafer 310. Each chip includes at least a sensing element 120 and at least a conductive pad 130, wherein the sensing element 120 is disposed on the upper surface 312 of the wafer 310, and the conductive pad 130 is disposed underneath of the upper surface 312 of the wafer 310 and is electrically connected to the sensing element 120. The material of the conductive pad 130 may be, for example, aluminum, copper, nickel, or other suitable metal materials. Furthermore, there is an optical cap 190 on the sensing element 120. A transparent substrate 192 and a dam structure 194 of the optical cap 190 form a space to protect the sensing element 120. An adhesive layer 196 of the optical cap 190 makes the dam structure 194 and the upper surface 312 of the wafer 310 steadily combined.

Please continue referring to FIG. 3B, the first via 152 extending from the lower surface 314 of the wafer 310 toward the upper surface 312 is formed to expose the conductive pad 130. The first via 152 may be formed by, for example but not limited to, a lithography process. Since the conductive pad 130 will form a solder ball or a wire-bonding after being packaged in the following process, the wafer 310 is etched and an end point of the first via 152 is formed. Then, as illustrated in FIG. 3, the thermal dissipation layer 140 is formed at the lower surface 314 of the wafer 310 by a process such as, for example, sputtering, evaporating, electroplating, electroless plating, and the material thereof may be, for example, aluminum. In some other embodiments of the present invention, other suitable conductive material, such as copper or nickel, can be used to manufacture the thermal dissipation layer 140.

In some embodiments of the present invention, a second via 154 extending from the lower surface 314 of the wafer 310 toward the upper surface 312 and exposing the adhesive layer 196 is formed meanwhile when the first via 152 is formed.

Please continue referring to FIG. 3C. As shown in FIG. 3C, an insulating layer 150 extending from the lower surface 314 of the wafer 310 toward the upper surface 312 is formed. To be more precise, the insulating layer 150 is deposited to cover the lower surface 314 of the wafer 310, sidewalls of the first via 152, the conductive pad 130, and the thermal dissipation layer 140. The material of the insulating layer 150 may be silicon oxide, silicon nitride, silicon oxynitride, or other suitable insulating materials. The insulating layer 150 is formed along the lower surface 314 of the wafer 310, sidewalls and the bottom of the first via 152, and the conductive pad 140 by chemical vapor deposition. In some embodiments of the present invention, the insulating layer 150 is obtained by using suitable insulating materials with suitable deposition parameters.

In some embodiments of the present invention, the insulating layer 150 also covers sidewalls of the second via 154, and cover the adhesive layer 196 exposed in the second via 154. The second via 154 can be used as a scribed line in the following processes to cut adjacent chips, this part will be discussed in detail later.

Please referring to FIG. 3D, a portion of the insulating layer 150 is removed to expose the thermal dissipation layer 140. When the thermal dissipation layer 140 is exposed, the insulating layer 150 covering the conductive pad 130 is also removed to expose the conductive pad 130. A portion of the insulating layer 150 is removed by a lithography process to remove a portion of the insulating layer 150 covering the thermal dissipation layer 140, and the end point of the etching process is set to expose the thermal dissipation layer 140. It should be noticed that the thermal dissipation layer 140 and the conductive pad 130 are exposed at the same photolithography so that additional photo masks are unnecessary.

Please continue referring to FIG. 3E, a conductive layer 170 is formed underneath the insulating layer 150 by a process such as, for example, sputtering, evaporating, electroplating, or electroless plating, and the material thereof may be, for example, aluminum, copper, nickel, or other suitable conductive materials. A conductive material is deposited over the insulating layer 150 and the conductive pad 130 first, followed by a photolithography process to pattern the aforementioned conductive material to form the conductive layer 170 underneath the insulating layer 150. And a portion of the conductive layer 170 is within the first via 152 and in contact with the 130 to be electrically connected to the 130. By the aforementioned step of patterning the conductive material, subsequently-formed signal-transmitting circuits of chip packages can be redistributed.

Please continue referring to FIG. 3F, a protective layer 180 is formed underneath the insulating layer 150 and the conductive layer 170 to cover and protect the conductive layer 170. The protective layer 180 can be formed by, for example but not limited to, brush coating external surfaces of the insulating layer 150 and the conductive layer 170 with solder mask. It should be noticed that a portion of the protective layer 180 fills into the first via 152 and the second via 154 but not fulfills the first via 152 and the second via 154. In the process of forming the protective layer 180, solder mask covers the 140 again. Therefore, the protective layer 180 is then patterned to remove a portion of the protective layer 180 and expose the thermal dissipation layer 140. And the protective layer 180 covering the conductive layer 170 is removed meanwhile to expose the conductive layer 170. In some embodiments of the present invention, the protective layer 180 is patterned by a lithography process to expose the thermal dissipation layer 140 and the conductive layer 170. It should be noticed that the thermal dissipation layer 140 and the conductive layer 170 are exposed under the same lithography process so that additional photo masks are unnecessary.

Please continue referring to FIG. 3G, thermal dissipation external connections 160a are formed underneath the thermal dissipation layer 140 and conduction external connections 160b are formed underneath the conductive layer 170. In some embodiments of the present invention, the thermal dissipation external connections 160a and the conduction external connections 160b are solder balls or bumps, which are industrially well-known structures, and the shape thereof may be, such as circular, ellipse, square, rectangular, which are not used to limit the present invention. In some other embodiments of the present invention, the thermal dissipation external connections 160a and the conduction external connections 160b are solder balls. It should be noticed that the thermal dissipation external connections 160a and the conduction external connections 160b are formed in the same process step. The conduction external connections 160b can be electrically connected to a printing circuit board in the subsequent processes to make the sensing element 120 electrically connected to the printing circuit board by the conductive pad 130, the conductive layer 170, and the conduction external connections 160b to perform signal-in or signal-out process. Similarly, the thermal dissipation external connections 160a are electrically connected to a printing circuit board in the subsequent processes as well. Therefore, the heat generated during the sensing element 120 operation can be transmitted into the printing circuit board by the thermal dissipation layer 140 and the thermal dissipation external connections 160a to lower the temperature of the sensing element 120 and increase the efficiency of the sensing element 120 effectively.

Finally, please refer to FIG. 3H, two adjacent chips were cut and separated by a scribe line 320 to form a chip package. To be more precise, the scribe line 320 is within the second via 154, and the protective layer 180, the insulating layer 150, the adhesive layer 196, the dam structure 194 and the transparent substrate 192 are cut in sequence along the scribe line 320 to separate the adjacent chips to form the chip package 100 as shown in FIG. 1.

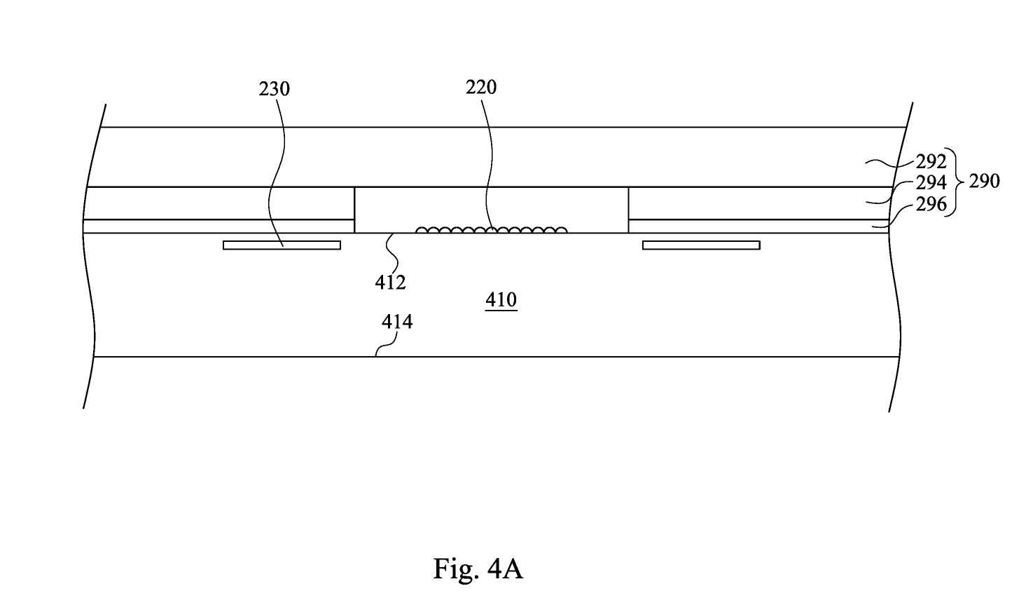

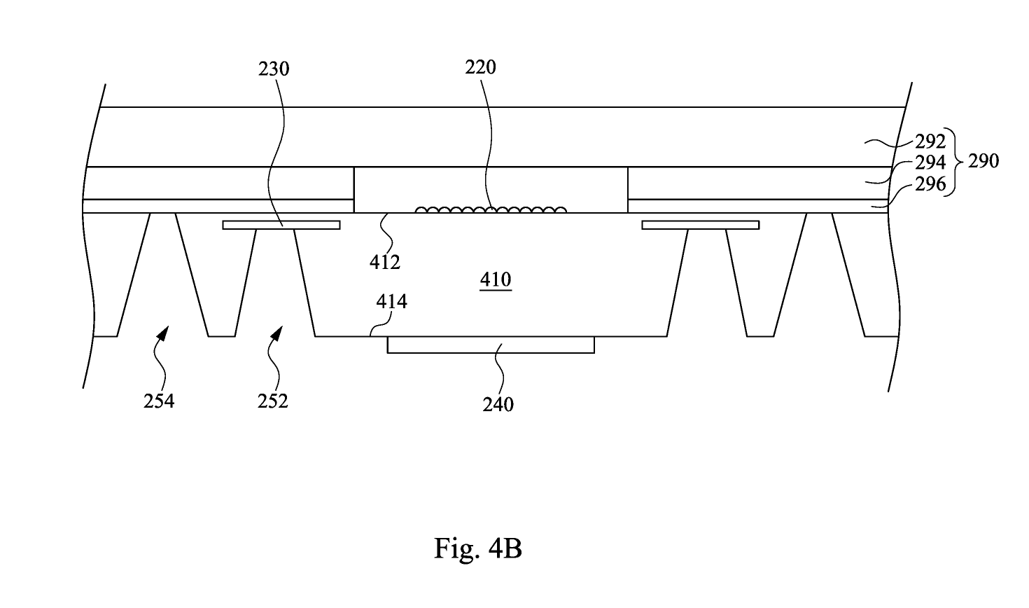

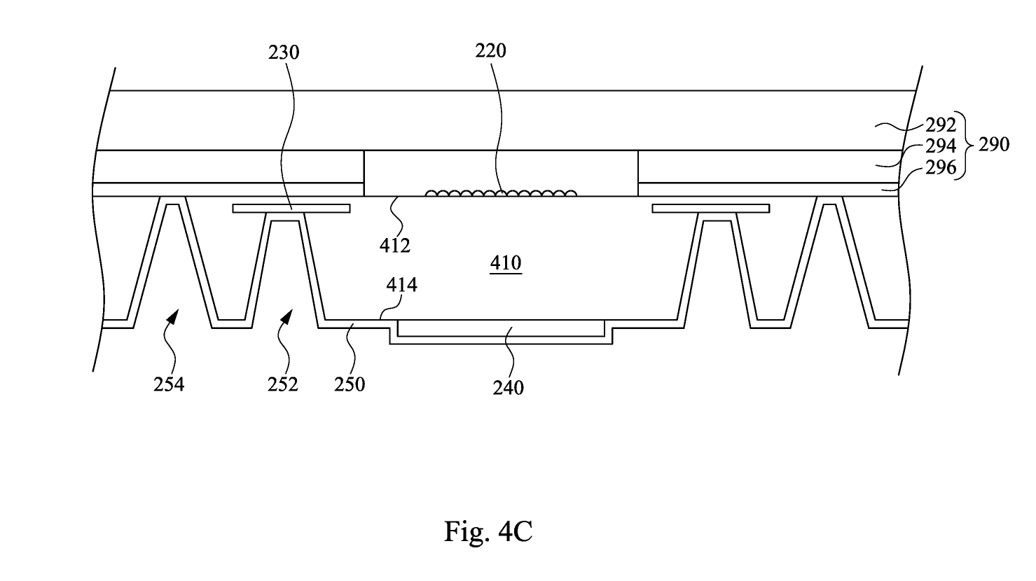

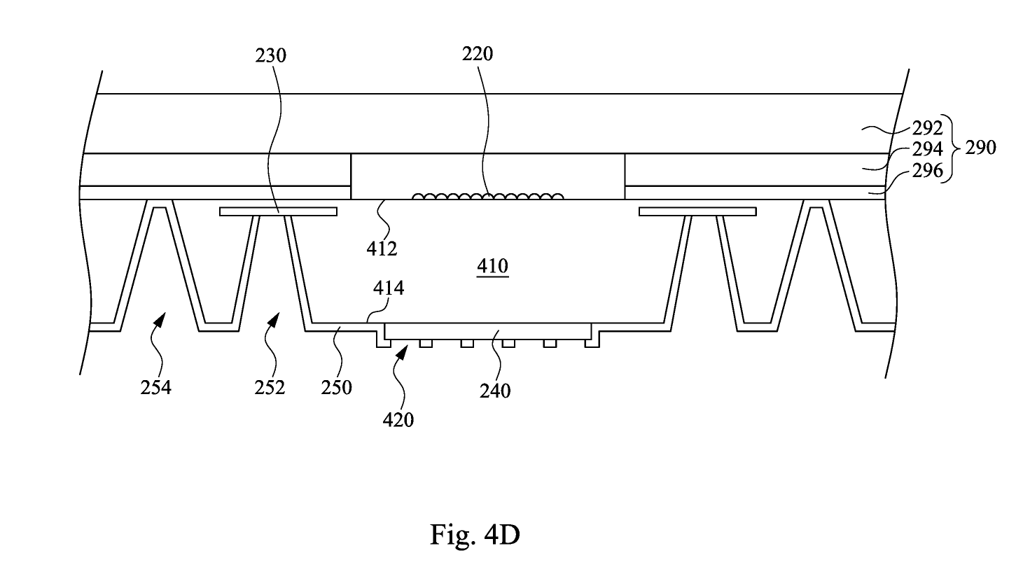

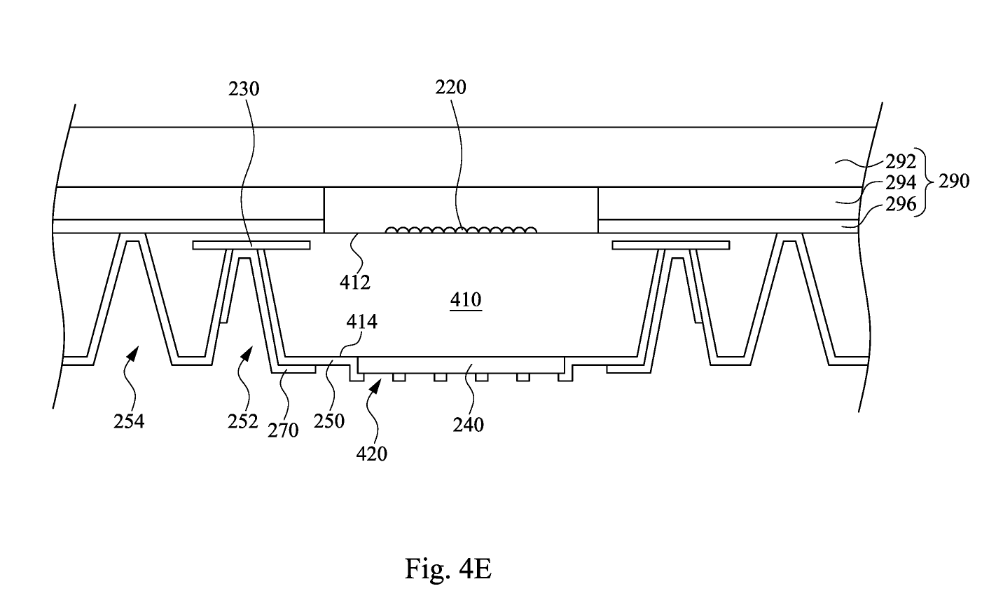

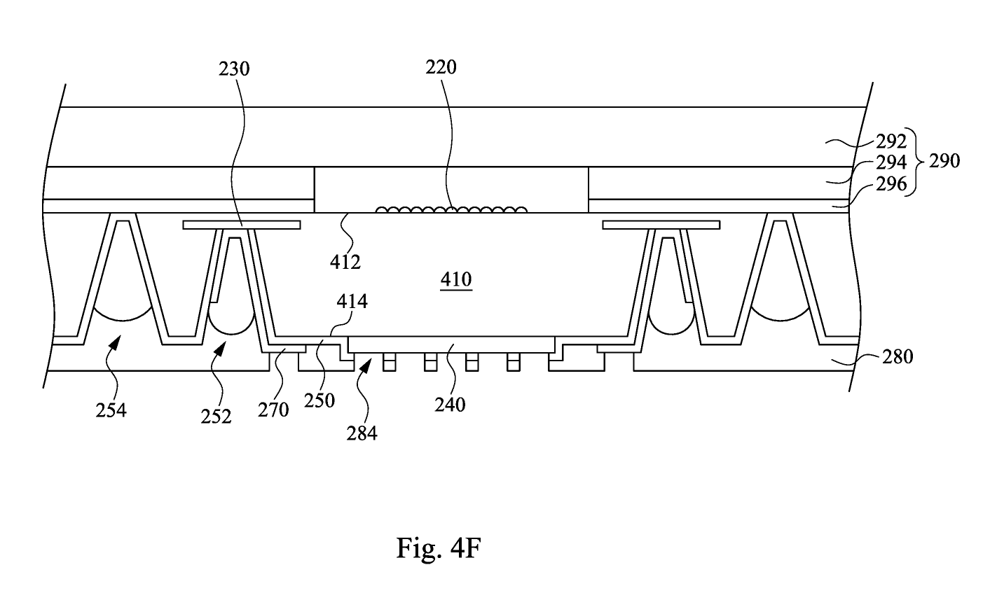

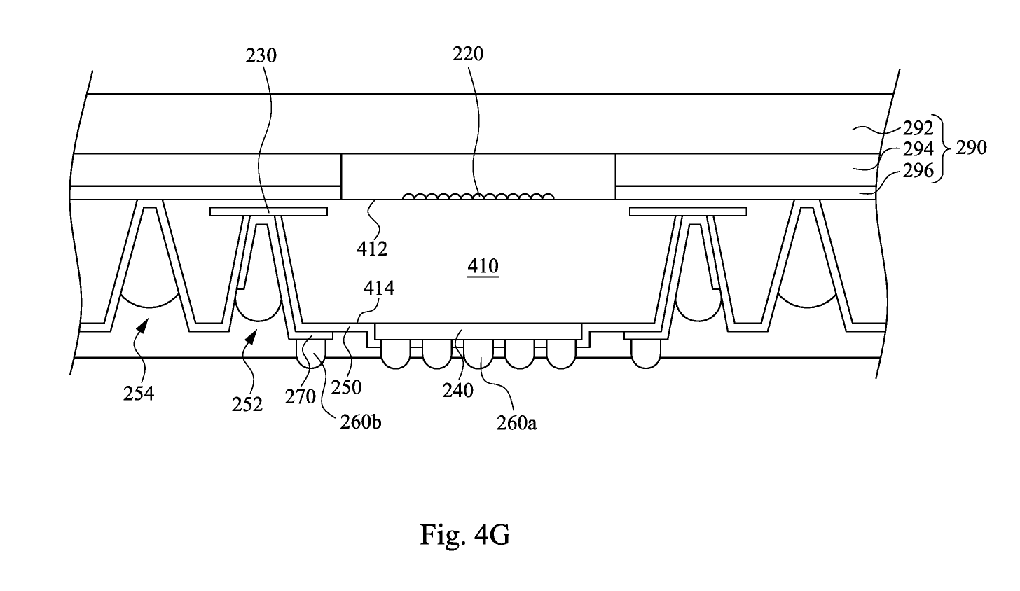

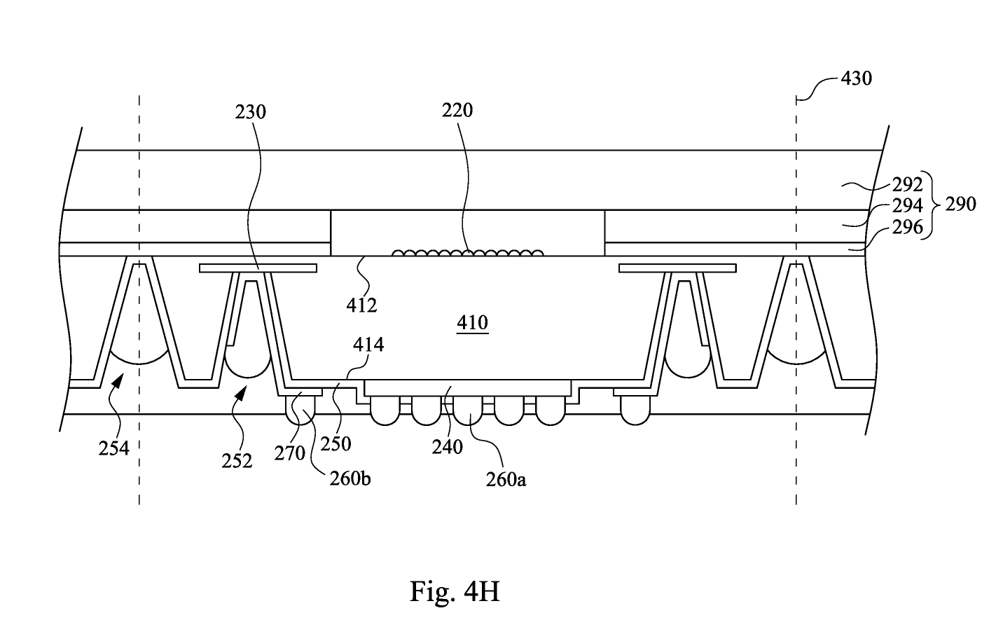

Please continue refer to FIGS. 4A through 4H for further understanding of the spirit of the present invention. FIGS. 4A through 4H illustrate cross-sectional views of the chip package in FIG. 2 at various stages of manufacturing. Please refer to FIG. 4A first, a wafer 410 having a plurality of chips and an upper surface 412 and a lower surface 414 opposite to each other is provided. The wafer 410 includes a semiconductor element, an inter-layer dielectric (ILD), an inter-metal dielectric (IMD), a passivation layer, and an interconnect metal structure, wherein the conductive pad 230 is one of the metal layers of the interconnect metal structure. For simplifying the description, what illustrated in FIG. 4A are portions of the chips of the wafer 410. Each chip includes at least a sensing element 220 and at least a conductive pad 230, wherein the sensing element 220 is over the upper surface 412 of the wafer 410 and the conductive pad 230 is underneath the upper surface 412 of the wafer 410 and electrically connected to the sensing element 220. The material of the conductive pad 230 may be, for example, aluminum, copper, nickel, or other suitable metal materials. Furthermore, an optical cap 290 is disposed over the sensing element 220. A transparent substrate 292 of the optical cap 290 forms a space with the dam structure 294 to protect the sensing element 220. An adhesive layer 296 of the optical cap 290 makes the dam structure 294 and the upper surface 212 of the chip 210 steadily combined.

Please continue referring to FIG. 4B, a first via 252 extends from the lower surface 414 of the wafer 410 towards the upper surface 412 to expose the conductive pad 230. The first via 252 may be formed by, for example but not limited to, a lithography process. Since the conductive pad 230 will form a solder ball or a wire-bonding after the sequent packaging process finished, the wafer 410 is etched to form the end point of the first via 252, which is set to expose the conductive pad 230. Then, as illustrated in FIG. 3, a thermal dissipation layer 240 is formed at the lower surface 414 of the wafer 410 by, for example, sputtering, evaporating, electroplating, electroless planting, and the material thereof may be, for example, aluminum. In other embodiments of the present invention, other suitable conductive materials, such as copper or nickel, can be used in manufacturing the thermal dissipation layer 240.

In some embodiments of the present invention, a second via 254 extending from the lower surface 414 of the wafer 410 towards the upper surface 412 and exposing the adhesive layer 296 is formed meanwhile when the first via 252 is formed.

Please continue referring to FIG. 4C. As illustrated in FIG. 4C, an insulating layer 250 is formed extending from the lower surface 414 of the wafer 410 toward the upper surface 412. To be more precise, the insulating layer 250 is deposited to cover the lower surface 414 of the wafer 410, sidewalls of the first via 252, the conductive pad 230 and the thermal dissipation layer 240. The material of the insulating layer 250 may be silicon oxide, silicon nitride, silicon oxynitride, or other suitable insulating materials. The insulating layer 250 is deposited along the lower surface 414 of the wafer 410, sidewalls and bottom of the first via 252, and the thermal dissipation layer 240 by chemical vapor deposition. In some embodiments of the present invention, the insulating layer 250 is obtained by using suitable insulating material and adjusting deposition parameters.

In some embodiments of the present invention, the insulating layer 250 also cover sidewalls of the second via 254 and the adhesive layer 296 exposed within the second via 254. The second via 254 can be used as a scribe line to separate two adjacent chips, which will be discussed in detail in the following description.

Please continue referring to FIG. 4D, a plurality of first openings 420 are formed on the insulating layer 250 to expose the thermal dissipation layer 240 and the conductive pad 230 meanwhile. A portion of the insulating layer 250 is removed by a lithography process to form a plurality of the first opening 420 on a portion of the insulating layer 250 covering the thermal dissipation layer 240, and the end point of the etching process is set to expose the thermal dissipation layer 240. When forming the first openings 420, a portion of the insulating layer 250 covering the conductive pad 230 is removed meanwhile to expose the conductive pad 230. It should be noticed that the conductive pad 230 and the thermal dissipation layer 240 can be exposed in the same lithography process without additional photo masks.

Please continue referring to FIG. 4E, a conductive layer 270 is formed underneath the insulating layer 250 by, for example, sputtering, evaporating, electroplating, or electroless plating, and is made of a material such as aluminum, copper, nickel, or other suitable conductive materials. A conductive material is deposited first to cover the insulating layer 250 and the conductive pad 230, followed by a lithography process to pattern the aforementioned conductive material to form the conductive layer 270 underneath the insulating layer 250, and a portion of the insulating layer 250 is within the first via 252 and in contact with the conductive pad 230 to be electrically connected to the conductive pad 230. By the aforementioned step of patterning the conductive material layer, the subsequently-formed signal-transmitting circuits of the chip package can be redistributed.

Please continue referring to FIG. 4F, a protective layer 280 is formed underneath the insulating layer 250 and the conductive layer 270 to protect the conductive layer 270. The material of the protective layer 280 may be, for example, solder mask, which can be formed by, for example but not limited to, brush-coated on external surfaces of the insulating layer 250 and the conductive layer 270. It should be noticed that a portion of the protective layer 280 is filled into the first via 252 and the second via 254 but not fulfills the first via 252 and the second via 254. In the process of forming the protective layer 280, the solder mask covers the thermal dissipation layer 240 again. Therefore, the protective layer 280 is then patterned to form a plurality of openings 284 to expose the thermal dissipation layer 240. To be more precise, a portion of the protective layer 280 at the first opening 420 is removed to form openings 284 extending from the lower surface 282 of the protective layer 280, penetrating the protective layer 280 and the insulating layer 250, and exposing the thermal dissipation layer 240. And a portion of the protective layer 280 covering the conductive layer 270 is removed as well to expose the conductive layer 270. In some embodiments of the present invention, the protective layer 280 is patterned by a lithography process to expose the thermal dissipation layer 240 and the conductive layer 270. It should be noticed that the thermal dissipation layer 240 and the conductive layer 270 are exposed under the same lithography process so that additional photo masks are unnecessary.

Please continue referring to FIG. 4G, thermal dissipation external connections 260a are formed underneath the thermal dissipation layer 240 to form conduction external connections 260b underneath the conductive layer 270. In some embodiments of the present invention, the thermal dissipation external connections 260a and the conduction external connections 260b are solder balls or bumps, which are industrially well-known structures, and the shape thereof may be circular, ellipse, square, rectangular, which are not used to limited the present invention. In some other embodiments of the present invention, the thermal dissipation external connections 260a and the conduction external connections 260b are solder balls. It should be noticed that the thermal dissipation external connections 260a and the conduction external connections 260b are formed in the same process step. The conduction external connections 260b can be connected to a printing circuit board in the following processes to make the sensing element 220 electrically connected to the printing circuit board by the conductive pad 230, the conductive layer 270, and the conduction external connections 260b to perform signal-in or signal-out process. Similarly, the thermal dissipation external connections 260a can be connected to a printing circuit board in the following processes. Therefore, the heat generated during the sensing element 220 operation can be transmitted to the printing circuit board by the thermal dissipation layer 240 and the thermal dissipation external connections 260a to lower the temperature of the sensing element 220 and increase the efficiency of the sensing element 220 effectively.

Finally, please refer to FIG. 4H; two adjacent chips were separated by a scribe line 430 to form a chip package. To be more precise, the scribe line 430 is within the second via 254, and the protective layer 280, the insulating layer 250, the adhesive layer 296, the dam structure 294 and the transparent substrate 292 are cut in sequence along the scribe line 430 to separate the adjacent chips to form the chip package 200 as shown in FIG. 2.

As known form the aforementioned embodiments of the present invention, the present invention has the following advantages. The chip package in the present invention has a thermal dissipation layer and thermal dissipation external connections in contact with the thermal dissipation layer, so that the heat generated during the chip operation can be transmitted into the external, such as printing circuit board, to increase the efficiency and lifetime of the chip. Furthermore, additional lithography process is not necessary in the manufacturing process of the chip package, which can be accomplished by forming openings exposing the thermal dissipation layer when forming openings on the passivation layer to expose a conductive pad. Similarly, the manufacturing process forms openings exposing the conductive pad when forming openings on the passivation layer to expose the conductive layer. Accordingly, the present invention makes the chip package has thermal dissipation function by a novel and simple manufacturing process.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A chip package, comprising:
a chip having an upper surface and a lower surface;
a sensing element disposed at the upper surface;
a thermal dissipation layer disposed at the lower surface; and
a plurality of thermal dissipation external connections disposed underneath and in contact with the thermal dissipation layer.

2. The chip package of claim 1, wherein the thermal dissipation layer is disposed at a place corresponding to the lower surface of the sensing element.

3. The chip package of claim 1, further comprising:
an insulating layer disposed at the lower surface and covering the thermal dissipation layer; and
a protective layer disposed at the lower surface and covering the insulating layer, a lower surface of the protective layer has a plurality of openings penetrating the protective layer and the insulating layer, and exposing the thermal dissipation layer,
wherein the thermal dissipation external connections are disposed within the openings and in contact with the thermal dissipation layer.

4. The chip package of claim 1, wherein the material of the thermal dissipation layer is a metal material.

5. The chip package of claim 4, wherein the metal material is aluminum.

6. The chip package of claim 1, wherein the thickness of the thermal dissipation layer is between 1 μm and 1.5 μm.

7. The chip package of claim 1, wherein the thermal dissipation external connections are solder balls.

8. A method of manufacturing a chip package, the method comprising:
providing a wafer having an upper surface, a lower surface, and a plurality of chips, wherein each of the chips comprises a sensing element disposed at the upper surface;
forming a thermal dissipation layer at the lower surface;
forming an insulating layer covering the thermal dissipation layer;
removing a portion of the insulating layer to expose the thermal dissipation layer;
forming a protective layer covering the insulating layer and the thermal dissipation layer;
removing a portion of the protective layer to expose the thermal dissipation layer; and
forming a plurality of thermal dissipation external connections underneath and in contact with the thermal dissipation layer.

9. The method of manufacturing the chip package of claim 8, wherein the chip further comprises a conductive pad disposed underneath the upper surface and electrically connected to the sensing element.

10. The method of manufacturing the chip package of claim 9, further comprising forming a plurality of openings in the wafer, wherein the openings extends from the lower surface toward the upper surface and exposes the conductive pad.

11. The method of manufacturing the chip package of claim 10, wherein the insulating layer covers sidewalls of the openings and the conductive pad.

12. The method of manufacturing the chip package of claim 11, wherein removing the portion of the insulating layer to expose the thermal dissipation layer further comprises:
removing a portion of the insulating layer to expose the conductive pad.

13. The method of manufacturing the chip package of claim 8, further comprising forming a conductive layer underneath the insulating layer, wherein the protective layer covers the conductive layer.

14. The method of manufacturing the chip package of claim 13, wherein removing the portion of the protective layer to expose the thermal dissipation layer further comprises:
removing a portion of the protective layer to expose the conductive layer.

15. The method of manufacturing the chip package of claim 14, further comprising forming a plurality of conductive connections underneath and in contact with the conductive layer, wherein the thermal dissipation external connections and the conductive connections are solder balls and are formed meanwhile in the same process step.

16. The method of manufacturing the chip package of claim 8, further comprising separating two adjacent chips along a scribe line to form a chip package.
